(19) United States
(12) Patent Application Publication
(10) Pub. No.: US 2023/0147337 A1
(43) Pub. Date: May 11, 2023

(54) THREE-DIMENSIONAL LTCC PACKAGE STRUCTURE

(71) Applicant: Chun-Hsia Chen, Taoyuan City (TW)

(72) Inventor: Chun-Hsia Chen, Taoyuan City (TW)

(73) Assignee: ONANO INDUSTRIAL CORP., Taoyuan City (TW)

(21) Appl. No.: 17/520,665

(22) Filed: Nov. 6, 2021

(51) Int. Cl. H01L 23/538; H01L 23/31; H01L 23/498

(52) U.S. Cl. CPC H01L 23/5385; H01L 23/5383; H01L 23/3121; H01L 23/5384; H01L 23/5389; H01L 23/49894; H01L 23/5386; H01L 2224/85; H01L 2223/58

(57) ABSTRACT

An LTCC package structure includes an interposer, two separators, a chip and a substrate. Chip I/O contacts and chip signal pathway nodes are disposed on a central portion and a peripheral portion of the interposer, respectively. The chip I/O contacts are electrically connected to the chip signal pathway nodes through transmission wires embedded in the interposer. The separators are provided with multiple signal junction wires therein. The chip is superposed on or under the interposer and electrically connected to the chip I/O contacts. Signal junction nodes are disposed on an upper surface of the substrate. Signal output contacts are disposed on a bottom surface of the substrate. The signal junction nodes are electrically connected to the signal output contacts through transmission wires embedded in the substrate. The substrate is superposed under the separators. The signal junction wires are electrically connected to the signal junction nodes.

### BACKGROUND

### Technical Field

The invention relates to low-temperature co-fired ceramics (LTCC), particularly to an LTCC package structure with three-dimensional connecting wires.

### Related Art

Introducing the silicon intermediate package structure can effectively avoid the problem resulting from inconsistent thermal expansion coefficients between a semiconductor and a package substrate to improve the structural stability of packaged products. As shown in FIG. 22, the package structure with a silicon interposer mounts a semiconductor chip 80 on a silicon interposer 90 with a silicon through hole 91. The silicon interposer 90 serves as an adapter plate to electrically connect the semiconductor chip 80 to a package substrate 95.

Such a silicon interposer can overcome the problem of inconsistent thermal expansion coefficients. Also, because of its shorter transmission distance, the electric transmission speed of the semiconductor chip 80 can be increased. However, both the difficulty of process technology and the processing cost are added because the silicon interposer utilizes the semiconductor manufacture process. With the enhancement of performance of the semiconductor chip 80, the number of input/output (I/O) also increases and the connecting wires circuit of the package structure becomes more complicated, so the planar connecting wires circuit framework of the conventional silicon interposer is gradually inadequate. Accordingly, how to avoid the above problems in the prior art is an urgent issue for the industry.

### SUMMARY

An object of the invention is to provide a three-dimensional LTCC package structure, which can reduce the package costs, increase the yield rate of packaged products, raise the setting density of packaged components and minify the volume of packaged products.

Another object of the invention is to provide a three-dimensional LTCC package structure, which can avoid thermal stress, delaminating of encapsulation adhesive and warpage of packaged products.

Still another object of the invention is to provide a three-dimensional LTCC package structure, whose ceramic interposer and substrate possess better thermal conductivity, weather resistance, hardness and insulation than conventional silicon interposers and PCB substrates.

To accomplish the above objects, the invention provides a three-dimensional LTCC package structure, which includes an interposer, a pair of separator strips, a semiconductor chip and a substrate. Multiple chip input/output (I/O) contacts are formed on a central portion of at least one of an upper surface and a lower surface of the interposer. Multiple chip signal pathway nodes are disposed on a peripheral portion thereof. The chip I/O contacts are electrically connected to the chip signal pathway nodes through transmission wires embedded in the interposer. The separator strips are provided with multiple signal junction wires therein. The signal junction wires penetrate through an upper surface and a lower surface of the separator strips. The separator strips are oppositely disposed on the lower surface of the interposer. The signal junction wires are electrically connected to the chip signal pathway nodes of the interposer. The semiconductor chip is superposed on or under the interposer and electrically connected to the chip I/O contacts. Multiple signal junction nodes are disposed on a peripheral portion of an upper surface of the substrate. Multiple signal output contacts are disposed on a bottom surface of the substrate. The signal junction nodes are electrically connected to the signal output contacts through transmission wires embedded in the substrate. The substrate is superposed under the separator strips. The signal junction wires of the separator strips are electrically connected to the signal junction nodes of the substrate. The interposer, the semiconductor chip and the separator strips are covered by encapsulation adhesive and the substrate.

In the invention, the interposer comprises a wire sublayer and a ceramic sublayer, the wire sublayer has a transmission wire disposed along a horizontal direction, the ceramic sublayer is disposed with a connecting conductor which perpendicularly penetrates through an upper surface and a lower surface of the ceramic sublayer, an end of the transmission wire of the interposer is electrically connected to one of the chip I/O contacts through the connecting conductor, and another end thereof is electrically connected to one of the chip signal pathway nodes.

In the invention, each of the wire sublayer and the ceramic sublayer is two in number, and the wire sublayers and the ceramic sublayers are interlacedly superposed.

In the invention, he wire sublayer is two in number, and the wire sublayers and the ceramic sublayer are interlacedly superposed.

In the invention, the ceramic sublayer is two in number, and the wire sublayer and the ceramic sublayers are interlacedly superposed.

In the invention, a cross-section of each separator strip is of a rectangular shape, an H-shape, a C-shape or an L-shape.

In the invention, the substrate comprises a wire layer, a ceramic layer and a base ceramic layer, the wire layer is the lowermost layer of the substrate, the ceramic layer is disposed with a connecting conductor which perpendicularly penetrates through an upper surface and a lower surface of the ceramic layer, the ceramic layer is the uppermost layer of the substrate, a peripheral area of an upper surface of the ceramic layer is provided with multiple signal junction nodes, the wire layer is provided with a transmission wire which is disposed along a horizontal direction, and the base ceramic layer is provided with multiple signal output contacts which are exposed on a bottom surface.

In the invention, in the substrate, an end of the transmission wire is electrically connected to one of the signal junction nodes through the connecting conductor, and another end thereof is electrically connected to one of the signal output contacts.

The invention further comprises a second pair of separator strips, each separator strip is placed on one of four sides of the lower surface of the interposer, the signal junction wires of the separator strips are electrically connected to the chip signal pathway nodes of the interposer, and a gap is formed between every adjacent two of the separator strips for serving as a filling passage of encapsulation adhesive.

The invention further comprises an additional combination unit electrically connected on the lamination combination, wherein the additional combination unit comprises:

an additional interposer, multiple chip input/output (I/O) contacts being disposed on a central portion of at least one of an upper surface and a lower surface of the additional interposer, multiple chip signal pathway nodes being disposed on a peripheral portion thereof, and the chip I/O contacts being electrically connected to the chip signal pathway nodes through transmission wires embedded in the interposer;

a pair of additional separator strips, provided with multiple signal junction wires therein, the signal junction wires penetrating through an upper surface and a lower surface of the separator strips, oppositely disposed on the lower surface of the additional interposer, and the signal junction wires of the additional separator strips being electrically connected to the chip signal pathway nodes of the additional interposer; and

a semiconductor chip, superposed on or under the additional interposer, and electrically connected to the chip I/O contacts of the additional interposer;

wherein the additional combination unit is superposed on the lamination combination, and the signal junction wires of the additional separator strips are electrically connected to the chip signal pathway nodes of the interposer.

The invention further comprises a second additional combination unit electrically connected on the additional combination unit, wherein the second additional combination unit is superposed on the additional combination unit, and the signal junction wires of the second additional separator strips are electrically connected to the chip signal pathway nodes of the additional interposer of the additional combination unit.

The invention further provides an interposer of a three-dimensional low-temperature co-fired ceramics (LTCC) package structure, the interposer comprises:

multiple chip input/output (I/O) contacts, disposed on a central portion of at least one surface of the interposer; and

multiple chip signal pathway nodes, disposed on a peripheral portion of the at least one surface of the interposer, and the chip I/O contacts being electrically connected to the chip signal pathway nodes through transmission wires embedded in the interposer.

The interposer of the invention further comprises a wire sublayer and a ceramic sublayer, wherein the wire sublayer has a transmission wire disposed along a horizontal direction, the ceramic sublayer is disposed with a connecting conductor which perpendicularly penetrates through an upper surface and a lower surface of the ceramic sublayer, an end of the transmission wire of the interposer is electrically connected to one of the chip I/O contacts through the connecting conductor, and another end thereof is electrically connected to one of the chip signal pathway nodes.

In the interposer of the invention, each of the wire sublayer and the ceramic sublayer is two in number, and the wire sublayers and the ceramic sublayers are interlacedly superposed.

In the interposer of the invention, the wire sublayer is two in number, and the wire sublayers and the ceramic sublayer are interlacedly superposed.

In the interposer of the invention, the ceramic sublayer is two in number, and the wire sublayer and the ceramic sublayers are interlacedly superposed.

### BRIEF DESCRIPTION OF THE DRAWINGS

FIG. 1 is a schematic view of the package structure of the invention;

FIG. 2 is a cross-sectional view of lamination of the interposer of the invention;

FIG. 3 is a top plan view of the interposer of the invention;

FIG. 4 is a cross-sectional view along line IV-IV in FIG. 3;

FIG. 5 is an assembled schematic view of combination of the interposer and the semiconductor chips;

FIG. 6 is a top plan view of the separator strips of the invention;

FIG. 7 is a cross-sectional view along line VI-VI in FIG. 6;

FIGS. 8-10 are cross-sectional views of the separator strip with different cross-sections;

FIG. 11 is a bottom plan view of combination of the separator strips and the interposer of the invention;

FIG. 12 is a cross-sectional view along line XII-XII in FIG. 11;

FIG. 13 is a bottom plan view of combination of the four separator strips and the interposer of another embodiment of the invention;

FIG. 14 is a schematic view of lamination of the substrate of the invention;

FIG. 15 is a top plan view of the substrate of the invention;

FIG. 16 is a bottom plan view of the substrate of the invention;

FIG. 17 is a cross-sectional view along line XVII-XVII in FIG. 11;

FIG. 18 is a cross-sectional view of combination of the interposer, the semiconductors, the separator strips and the substrate;

FIG. 19 is a schematic view of the package structure of the invention after being encapsulated with adhesive;

FIG. 20 is a cross-sectional view of an additional combination unit of another embodiment of the invention;

FIG. 21 is a schematic view of the package structure of the another embodiment of the invention, which shows the additional combination unit is added on the lamination combination; and

FIG. 22 is a schematic view of a conventional package structure using a silicon interposer.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

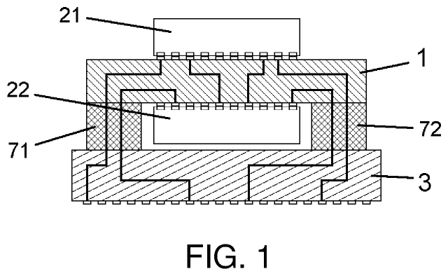

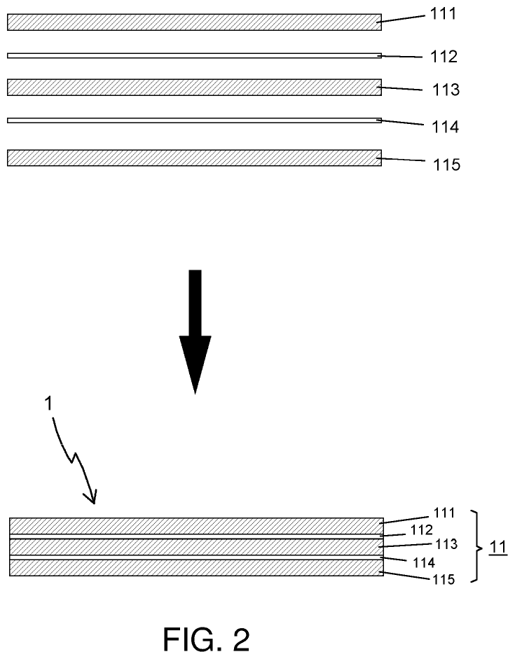

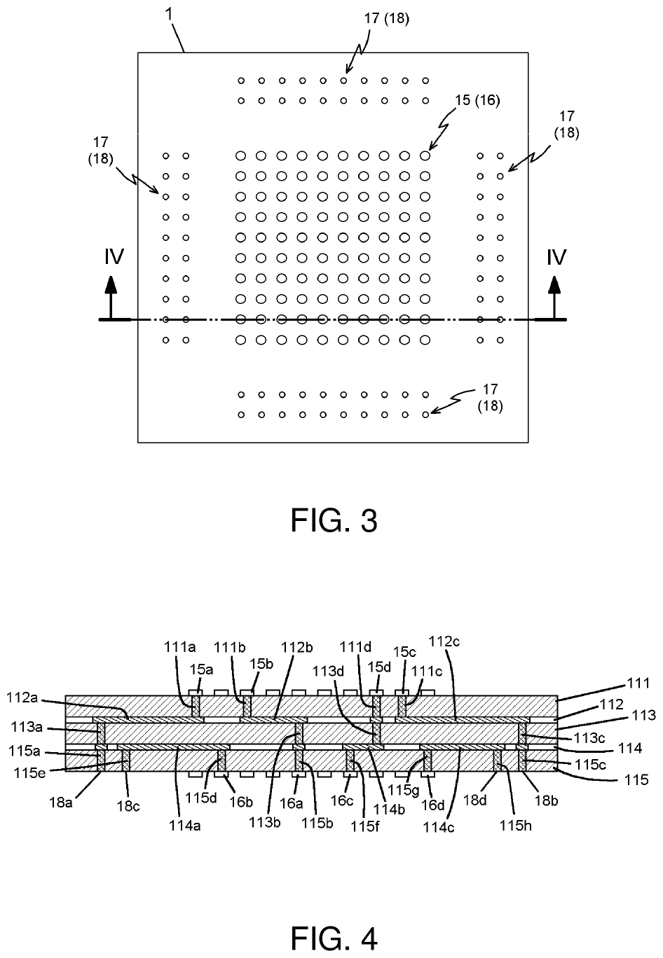

FIG. 1 depicts the most simplified embodiment of the three-dimensional LTCC package structure of the invention, which includes an interposer 1, a first semiconductor chip 21, a second semiconductor chip 22, two separator strips 71, 72 and a substrate 3. The structure of the interposer 1 is depicted in FIGS. 2-4. Multiple chip input/output (I/O) contacts 15, 16 are formed on central portions of an upper surface and a lower surface of the interposer 1. Multiple chip signal pathway nodes 17, 18 are disposed on a peripheral portion thereof. And a three-dimensional connection framework is disposed in the plate. The interposer 1 includes at least one wire sublayer and at least one ceramic sublayer. The wire sublayer is formed on the ceramic layer. The wire sublayers and the ceramic sublayers are interlacedly superposed. The wire sublayer has transmission wires which are horizontally arranged and disposed on the ceramic sublayer by the yellow light process or the screen printing. The ceramic sublayer is disposed with connecting conductors which perpendicularly penetrate through an upper surface and a lower surface of the ceramic sublayer. As a result, the three-dimensional connection framework can be established. The interposer 1 is formed by the processes of stacking, lamination, knife cutting, burn-out and sintering.

FIG. 4 further depicts the internal structure of the interposer 1. The interposer 1 includes a first ceramic sublayer 111, a first wire sublayer 112, a second ceramic sublayer 113, a second wire sublayer 114 and a third ceramic sublayer 115. According to the design requirements, each ceramic sublayer 111, 113, 115 is disposed with multiple connecting conductors at corresponding positions. For example, the first transmission wire 112a on the first wire sublayer 112 is electrically connected both to the upper chip I/O contact 15a through the connecting conductor 111a and to the lower chip signal pathway node 18a through the connecting conductors 113a, 115a; the second transmission wire 112b on the first wire sublayer 112 is electrically connected both to the upper chip I/O contact 15b through the connecting conductor 111b and to the lower chip I/O contact 16a through the connecting conductors 113b, 115b; the third transmission wire 112c on the first wire sublayer 112 is electrically connected both to the upper chip I/O contact 15c through the connecting conductor 111c and to the lower chip signal pathway node 18b through the connecting conductors 113c, 115c; the first transmission wire 114a on the second wire sublayer 114 is electrically connected both to the lower chip I/O contact 16b through the connecting conductor 115d and to the lower chip signal pathway node 18c through the connecting conductors 115e; the second transmission wire 114b on the second wire sublayer 114 is electrically connected both to the upper chip I/O contact 15d through the connecting conductor 113d, 111d and to the lower chip I/O contact 16c through the connecting conductors 115f; and the third transmission wire 114c on the second wire sublayer 114 is electrically connected both to the lower chip I/O contact 16d through the connecting conductor 115g and to the lower chip signal pathway node 18d through the connecting conductors 115h.

In the above embodiment of the invention, the interposer 1 has two wire sublayers and three ceramic sublayers. In practice, however, the number of the sublayers is not limited. For example, a combination of three wire sublayers and two ceramic sublayers is also available. Such a combination has more wire sublayers and less ceramic sublayers, so the interposer may save the processing costs and material costs and provide more chip I/O contacts to improve the performance of the connection circuit. In detail, when the interposer 1 has more sublayers, it means the interposer may provide more chip I/O contacts to integrate more semiconductor chips and various electronic components in a single package structure.

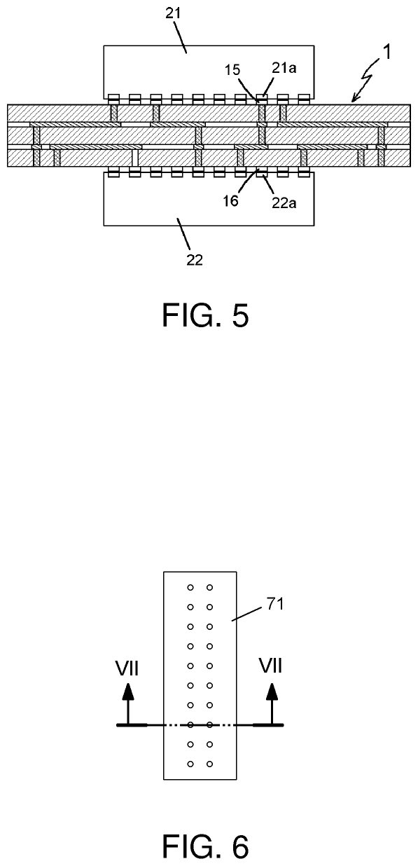

Please refer to FIG. 5. The two semiconductor chips 21, 22 are disposed on an upper surface and a lower surface of the interposer 1, respectively. The first semiconductor chip 21 is assembled on the interposer 1 and connected with the chip I/O contacts 15 by micro bumps. Pins 21a of the first semiconductor chip 21 are separately electrically connected with and fixed to the chip I/O contacts 15. Identically, the second semiconductor chip 22 is disposed under the interposer 1 and connected with the chip I/O contacts 16 by micro bumps. Pins 22a of the second semiconductor chip 22 are separately electrically connected with and fixed to the chip I/O contacts 16.

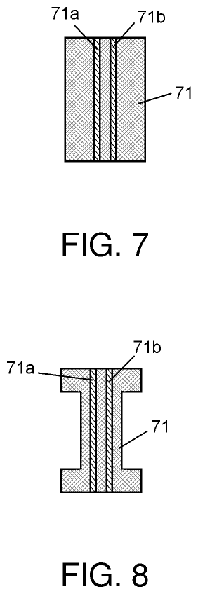

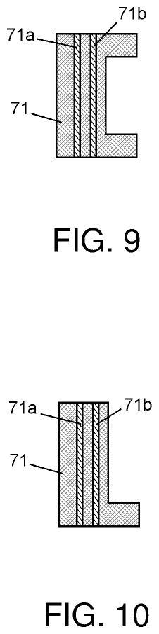

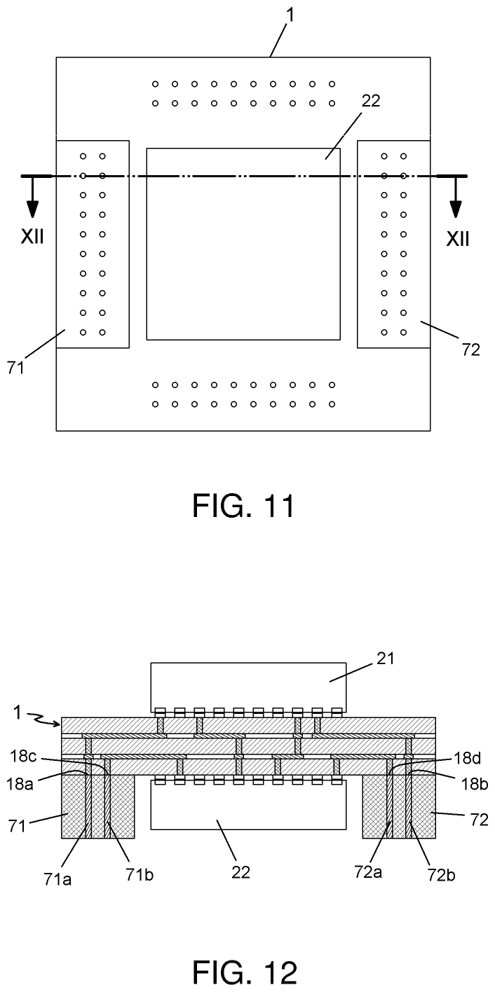

As shown in FIGS. 6, 7, 11 and 12, the two separator strips 71, 72 are oppositely disposed on the lower surface of the interposer 1. The inside of each separator strip 71, 72 is provided with multiple signal junction wires 71a, 71b, 72a, 72b. Ends of the signal junction wires 71a, 71b, 72a, 72b are extended and disposed on the upper surface and lower surface of the separator strips 71, 72. The pair of separator strips 71, 72 is symmetrically disposed on the opposite sides of the lower surface of the interposer 1. The signal junction wires 71a, 71b, 72a, 72b of the separator strips 71, 72 are electrically connected to the chip signal pathway nodes 18a, 18c, 18d, 18b of the interposer 1. In the embodiment, a cross-section of each separator strip 71, 72 is of a rectangular shape, but not limited to this in practice, an H-shape, a C-shape or an L-shape as shown in FIGS. 8-10 is also available. For example, the separator strip with an H-shaped cross-section can provide a firm connection structure, increase the receiving space of chips and save the material costs.

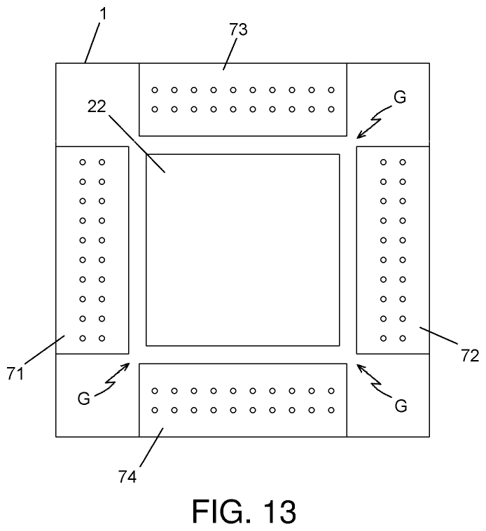

In addition, as shown in FIG. 13, the invention further provides a structural solution with two pair of separator strips, which arranges a separator strip 71, 72, 73, 74 on each of four sides of the interposer 1. A length of each separator strip 71, 72, 73, 74 is less than a length of each side of the interposer 1 so as to form a gap G between every adjacent two of the separator strips 71, 72, 73, 74. A passage formed by the gap G can be used to fill encapsulation adhesive into everywhere in the chip installation space to enhance the adhesion stability of the chip package structure.

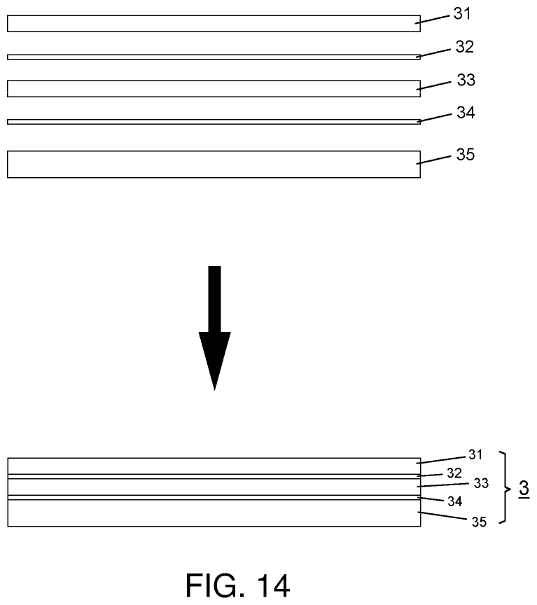

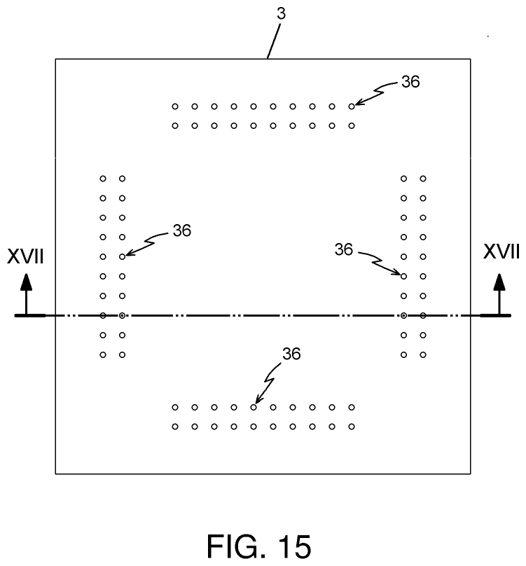

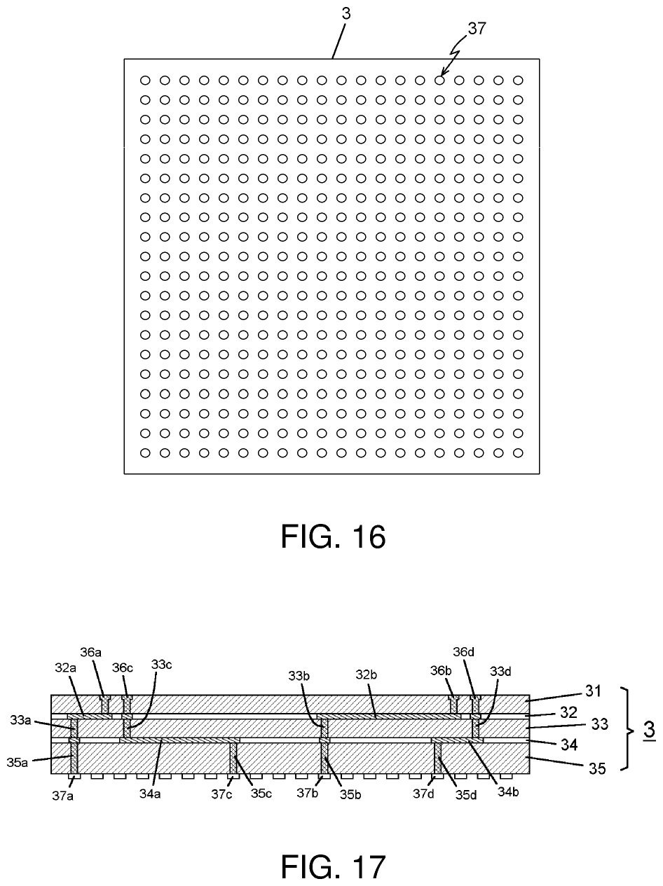

Please refer to FIGS. 14-18. The substrate 3 includes at least one wire layer, at least one ceramic layer and a base ceramic layer. The wire layer is formed on the ceramic layer. The wire layers and the ceramic layers are interlacedly superposed. The wire layer has transmission wires which are horizontally arranged and disposed on the ceramic layer by the yellow light process or the screen printing. Multiple signal output contacts are disposed on the base ceramic layer. The ceramic layer is formed with connecting conductors which perpendicularly penetrate through an upper surface and a lower surface of the ceramic layer. The connecting conductors electrically connect the transmission wires or contacts, which are located on different layers. As a result, a three-dimensional connection is formed in the substrate.

The substrate 3 is composed of a first ceramic layer 31, a first wire layer 32, a second ceramic layer 33, a second wire layer 34 and a base ceramic sublayer 35, which are combined by the processes of stacking, lamination, knife cutting, burn-out and sintering. A peripheral area of an upper surface of the first ceramic layer 31 which is the upmost layer of the substrate 3, is provided with multiple signal junction nodes 36. The base ceramic layer 35 is provided with multiple signal output contacts 37 which are exposed on the bottom surface. According to the design requirements, each ceramic layer 31, 33, 35 is disposed with multiple connecting conductors at corresponding positions. For example, the first transmission wire 32a on the first wire layer 32 is electrically connected both to the signal junction node 36a and to the signal output contact 37a of the bottom through the connecting conductors 33a, 35a; the second transmission wire 32b on the first wire layer 32 is electrically connected both to the signal junction node 36b and to the signal output contact 37b of the bottom through the connecting conductors 33b, 35b; the first transmission wire 34a on the second wire layer 34 is electrically connected both to the signal junction node 36c through the connecting conductor 33c and to the signal output contact 37c of the bottom through the connecting conductors 35c; and the second transmission wire 34b on the second wire layer 34 is electrically connected both to the signal junction node 36d through the connecting conductor 33d and to the signal output contact 37d of the bottom through the connecting conductors 35d.

The substrate 3 of the embodiment of the invention has two wire layers and three ceramic layers. In practice, however, the number of the sublayers is not limited. For example, For example, a combination of two wire layers, one ceramic layer and one base ceramic layer is also available. In comparison with the above embodiment, such a combination has less ceramic layers, so the substrate may save the processing costs and material costs.

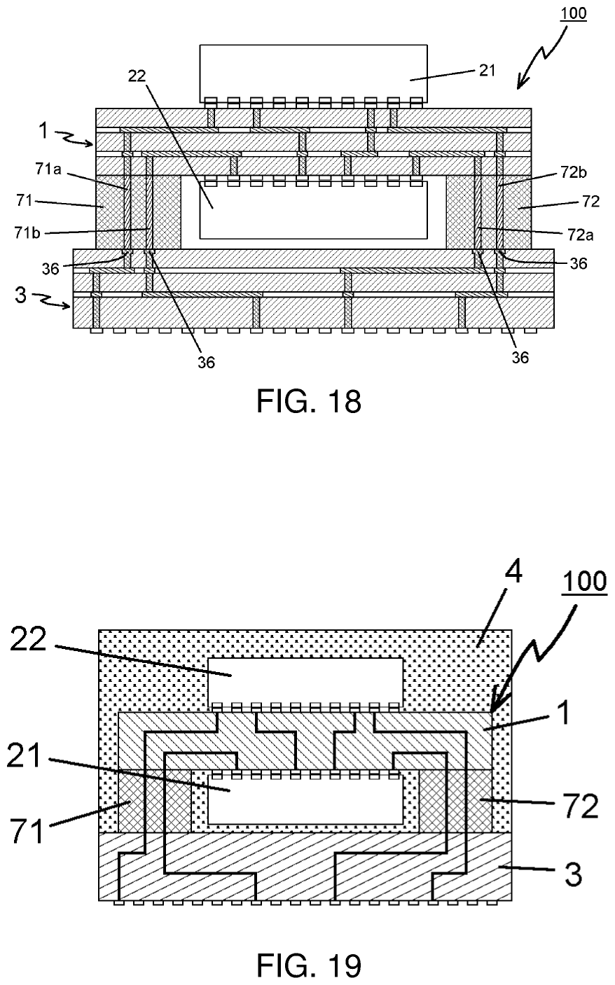

As shown in FIG. 18, the substrate 3 is superposed under the separator strips 71, 72. The signal junction wires 71a, 71b, 72a, 72b of the separator strips 71, 72 are electrically connected to the signal junction nodes 36 of the substrate 3 at corresponding positions. As a result, the interposer 1, the semiconductor chips (the first semiconductor chip 71 and the second semiconductor chip 72), the separator strips 71, 72 and the substrate 3 jointly form a lamination combination 100.

Finally, the lamination combination 100 is covered by encapsulation adhesive to obtain the three-dimensional package structure of the invention.

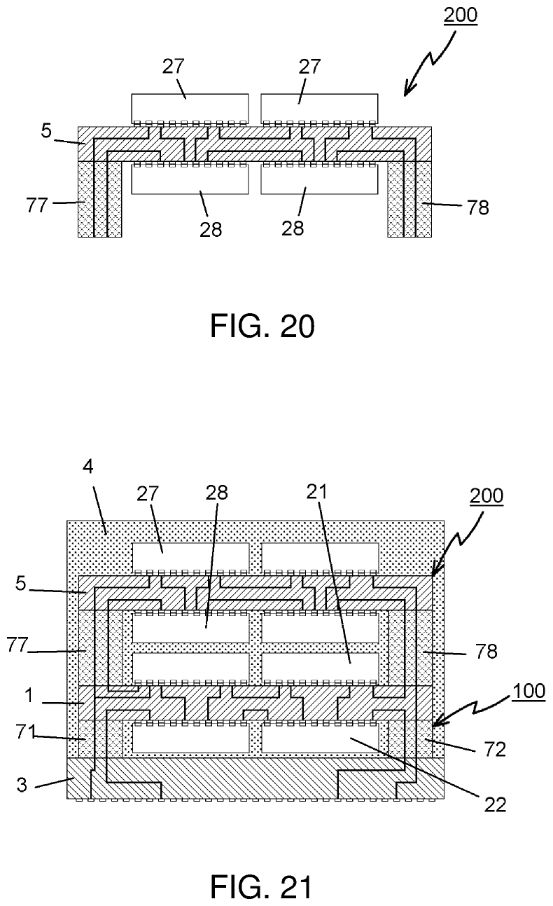

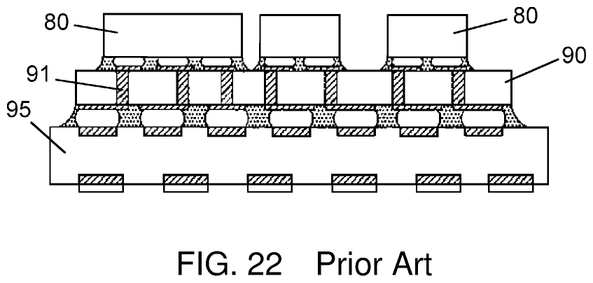

Please refer to FIGS. 20 and 21, which shows another embodiment of the invention. This embodiment adds an additional combination unit 200 on the lamination combination 100 of the above embodiment. The additional combination unit 200 shown in FIG. 20 includes a second interposer 5, a pair of second separator strips 77, 78 and two semiconductor chips 27, 28. The second interposer 5 is substantially identical to the interposer 1 of the above embodiment in structure. The pair of second separator strips 77, 78 is substantially identical to the separator strips 71, 72 of the above embodiment in structure. Signal junction wires in the second separator strips are electrically connected to chip signal pathway nodes of the second interposer 5. The two semiconductor chips 27, 28 are separately installed on an upper surface and a lower surface of the second interposer 5 and electrically connected to the chip I/O contacts. Please refer to FIG. 21. The additional combination unit 200 is disposed on the lamination combination 100 and signal junction wires of the pair of second separator strips 77, 78 of the additional combination unit 200 are electrically connected to chip signal pathway nodes of the interposer 1 if the lamination combination 100 so as to electrically connect the additional combination unit 200 with the lamination combination 100. The additional combination unit 200 allows to install multiple semiconductor chips or other electronic components. A height of the separator strip of the invention may depend on the requirements of the chip receiving space. For example, the pair of second separator strips 77, 78 for installing two layers of chips is greater than the separator strips 71, 72 for installing one layer of chips in height.

The above embodiment discloses a chip package structure with adding an additional combination unit 200 on a lamination combination 100. In practice, however, the additional combination unit 200 may still be connected with one or more additional combination units. The number of lamination of the additional combination units is not limited. More layers of lamination allow more semiconductor chips or other electronic components to be received in the package structure.

While this disclosure has been described by means of specific embodiments, numerous modifications and variations could be made thereto by those skilled in the art without departing from the scope and spirit of this disclosure set forth in the claims.

What is claimed is:

1. A three-dimensional low-temperature co-fired ceramics (LTCC) package structure comprising:
an interposer, multiple chip input/output (I/O) contacts being disposed on a central portion of at least one of an upper surface and a lower surface of the interposer, multiple chip signal pathway nodes being disposed on a peripheral portion thereof, and the chip I/O contacts being electrically connected to the chip signal pathway nodes through transmission wires embedded in the interposer;
a pair of separator strips, provided with multiple signal junction wires therein, the signal junction wires penetrating through an upper surface and a lower surface of the separator strips, the separator strips being oppositely disposed on the lower surface of the interposer, and the signal junction wires being electrically connected to the chip signal pathway nodes of the interposer;
a semiconductor chip, superposed on or under the interposer, and electrically connected to the chip I/O contacts; and
a substrate, multiple signal junction nodes being disposed on a peripheral portion of an upper surface of the substrate, multiple signal output contacts being disposed on a bottom surface of the substrate, the signal junction nodes being electrically connected to the signal output contacts through transmission wires embedded in the substrate, the substrate being superposed under the separator strips, and the signal junction wires of the separator strips being electrically connected to the signal junction nodes of the substrate;
wherein the interposer, the semiconductor chip, the separator strips and the substrate are assembled to form a lamination combination, and the semiconductor chip and the separator strips are covered by encapsulation adhesive and the substrate.

2. The three-dimensional LTCC package structure of claim 1, wherein the interposer comprises a wire sublayer and a ceramic sublayer, the wire sublayer has a transmission wire disposed along a horizontal direction, the ceramic sublayer is disposed with a connecting conductor which perpendicularly penetrates through an upper surface and a lower surface of the ceramic sublayer, an end of the transmission wire of the interposer is electrically connected to one of the chip I/O contacts through the connecting conductor, and another end thereof is electrically connected to one of the chip signal pathway nodes.

3. The three-dimensional LTCC package structure of claim 2, wherein each of the wire sublayer and the ceramic sublayer is two in number, and the wire sublayers and the ceramic sublayers are interlacedly superposed.

4. The three-dimensional LTCC package structure of claim 2, wherein the wire sublayer is two in number, and the wire sublayers and the ceramic sublayer are interlacedly superposed.

5. The three-dimensional LTCC package structure of claim 2, wherein the ceramic sublayer is two in number, and the wire sublayer and the ceramic sublayers are interlacedly superposed.

6. The three-dimensional LTCC package structure of claim 1, wherein a cross-section of each separator strip is of a rectangular shape, an H-shape, a C-shape or an L-shape.

7. The three-dimensional LTCC package structure of claim 1, wherein the substrate comprises a wire layer, a ceramic layer and a base ceramic layer, the wire layer is the lowermost layer of the substrate, the ceramic layer is disposed with a connecting conductor which perpendicularly penetrates through an upper surface and a lower surface of the ceramic layer, the ceramic layer is the uppermost layer of the substrate, a peripheral area of an upper surface of the ceramic layer is provided with multiple signal junction nodes, the wire layer is provided with a transmission wire which is disposed along a horizontal direction, and the base ceramic layer is provided with multiple signal output contacts which are exposed on a bottom surface.

8. The three-dimensional LTCC package structure of claim 7, wherein in the substrate, an end of the transmission wire is electrically connected to one of the signal junction nodes through the connecting conductor, and another end thereof is electrically connected to one of the signal output contacts.

9. The three-dimensional LTCC package structure of claim 1, further comprising a second pair of separator strips, wherein each separator strip is placed on one of four sides of the lower surface of the interposer, the signal junction wires of the separator strips are electrically connected to the chip signal pathway nodes of the interposer, and a gap is formed between every adjacent two of the separator strips for serving as a filling passage of encapsulation adhesive.

10. The three-dimensional LTCC package structure of claim 1, further comprising an additional combination unit electrically connected on the lamination combination, wherein the additional combination unit comprises:
an additional interposer, multiple chip input/output (I/O) contacts being disposed on a central portion of at least one of an upper surface and a lower surface of the additional interposer, multiple chip signal pathway nodes being disposed on a peripheral portion thereof, and the chip I/O contacts being electrically connected to the chip signal pathway nodes through transmission wires embedded in the interposer;
a pair of additional separator strips, provided with multiple signal junction wires therein, the signal junction wires penetrating through an upper surface and a lower surface of the separator strips, oppositely disposed on the lower surface of the additional interposer, and the signal junction wires of the additional separator strips being electrically connected to the chip signal pathway nodes of the additional interposer; and
a semiconductor chip, superposed on or under the additional interposer, and electrically connected to the chip I/O contacts of the additional interposer;
wherein the additional combination unit is superposed on the lamination combination, and the signal junction wires of the additional separator strips are electrically connected to the chip signal pathway nodes of the interposer.

11. The three-dimensional LTCC package structure of claim 1, further comprising a second additional combination unit electrically connected on the additional combination unit, wherein the second additional combination unit is superposed on the additional combination unit, and the signal junction wires of the second additional separator strips are electrically connected to the chip signal pathway nodes of the additional interposer of the additional combination unit.

12. An interposer of a three-dimensional low-temperature co-fired ceramics (LTCC) package structure, comprising:
multiple chip input/output (I/O) contacts, disposed on a central portion of at least one surface of the interposer; and
multiple chip signal pathway nodes, disposed on a peripheral portion of the at least one surface of the interposer, and the chip I/O contacts being electrically connected to the chip signal pathway nodes through transmission wires embedded in the interposer.

13. The interposer of claim 12, further comprising a wire sublayer and a ceramic sublayer, wherein the wire sublayer has a transmission wire disposed along a horizontal direction, the ceramic sublayer is disposed with a connecting conductor which perpendicularly penetrates through an upper surface and a lower surface of the ceramic sublayer, an end of the transmission wire of the interposer is electrically connected to one of the chip I/O contacts through the connecting conductor, and another end thereof is electrically connected to one of the chip signal pathway nodes.

14. The interposer of claim 13, wherein each of the wire sublayer and the ceramic sublayer is two in number, and the wire sublayers and the ceramic sublayers are interlacedly superposed.

15. The interposer of claim 13, wherein the wire sublayer is two in number, and the wire sublayers and the ceramic sublayer are interlacedly superposed.

16. The interposer of claim 13, wherein the ceramic sublayer is two in number, and the wire sublayer and the ceramic sublayers are interlacedly superposed.
